(19) United States
(12) Patent Application Publication
(10) Pub. No.: US 2026/0208316 A1
(43) Pub. Date: Jul. 23, 2026

(54) SUBSTRATE POLISHING SYSTEM

(71) Applicant: KCTECH CO., LTD, Anseong-si (KR)

(72) Inventors: Hee Sung CHAE, Pyeongtaek-si (KR); Seung Eun LEE, Seoul (KR); Geun Sik YUN, Anseong-si (KR)

(73) Assignee: KCTECH CO., LTD., Anseong-si (KR)

(21) Appl. No.: 19/560,908

(22) Filed: Mar. 9, 2026

Related U.S. Application Data
(63) Continuation of application No. 17/579,189, filed on Jan. 19, 2022.

(30) Foreign Application Priority Data
Feb. 26, 2021 (KR) 10-2021-0026897

(51) Int. Cl. B24B 37/10; B24B 37/30; B24B 37/34; B24B 57/02

(52) U.S. Cl. CPC B24B 37/105; B24B 37/30; B24B 37/345; B24B 57/02

(57) ABSTRACT

A substrate polishing system may include a substrate transfer unit to support a bottom surface of a substrate and transfer the substrate while forming a transfer orbit in a circle by a rotational motion, at least one carrier to perform polishing on the substrate received from the substrate transfer unit, and a loader to load the substrate which is seated on the substrate transfer unit to the carrier or unload a substrate placed on the carrier to the substrate transfer unit.

### CROSS-REFERENCE TO RELATED APPLICATIONS

This application is a continuation of U.S. patent application Ser. No. 17/579,189, filed Jan. 19, 2022, which claims the benefit of priority under 35 U.S.C. § 119 to Republic of Korea Patent Application No. 10-2021-0026897, filed Feb. 26, 2021, the contents of which are incorporated herein by reference in their entirety.

### BACKGROUND

### Field of the Invention

One or more example embodiments relate to a substrate polishing system.

### 2. Description of the Related Art

In the process of manufacturing a semiconductor device, a chemical mechanical polishing or planarization (CMP) process including polishing, buffing, and cleaning is required. The semiconductor device may be configured to have a multilayer structure wherein a transistor device with a diffusion region is provided at a substrate layer. In the substrate layer, a connecting metallic line may be patterned and electrically connected to the transistor device that constitutes a functional device. A patterned conductive layer may be insulated from other conductive layers by an insulator such as silicon dioxide. As more metal layers and corresponding insulating layers are formed, a need to flatten insulators may increase. Without flattening, manufacturing an additional metal layer may be more difficult due to numerous irregularities in a surface. In addition, the metallic line pattern may be formed of an insulator and a metal CMP process may be performed to remove excess metal.

To increase the production efficiency of the CMP process, reducing a waiting time between processes and performing the processes in parallel is required. For example, a production efficiency of the CMP process may be improved by reducing a substrate transfer path and simultaneously performing transferring and polishing on a plurality of substrates.

The above description is information the inventor(s) acquired during the course of conceiving the present disclosure, or already possessed at the time, and is not necessarily art publicly known before the present application was filed.

### SUMMARY

Example embodiments provide a substrate polishing system that may simultaneously perform transferring, polishing, and cleaning on a plurality of substrates.

Example embodiments also provide a substrate polishing system that may enhance a substrate yield rate by maintaining a substrate in a constant state during a process of transferring, waiting, and cleaning the substrate.

According to an aspect, there is provided a substrate polishing system including a substrate transfer unit to support a bottom surface of a substrate and transfer the substrate while forming a transfer orbit in a circle by a rotational motion, at least one carrier to perform polishing on the substrate received from the substrate transfer unit, and a loader to load the substrate which is seated on the substrate transfer unit to the carrier or unload a substrate placed on the carrier to the substrate transfer unit.

The loader may include a first nozzle to spray a fluid.

The loader may further include a rotator to rotate on an axis perpendicular to a ground, a loading plate to support the bottom surface of the substrate the loading plate being rotatable by the rotator, and a protrusion connected to an outside of the loading plate and protruding upwardly.

During a process of loading or unloading the substrate by moving the loader upward, an upper surface of the protrusion may be placed higher than a bottom surface of the carrier.

The first nozzle may be placed on an upper surface of the loading plate.

The first nozzle may be placed on an inner surface of the protrusion.

The loader may vertically move upwards or downwards from the substrate transfer unit.

The substrate transfer unit may include a shaft to rotate on an axis perpendicular to a ground, and at least one transfer arm to support a bottom surface of the substrate and transfer the substrate while forming a transfer orbit in a circle by rotation of the shaft.

The transfer arm may receive an unpolished substrate at a first point on the transfer orbit and transfer the unpolished substrate to the carrier by moving to a second point on the transfer orbit.

The transfer arm may receive a polished substrate from the carrier at the second point and transfer the polished substrate to a next process by moving to the first point.

A plurality of transfer arms may be provided, and each disposed at an equiangular interval with the shaft as a center.

When one of the plurality of transfer arms is placed on the first point, at least one of the plurality of transfer arms may be placed on the second point.

The loader may be placed on the second point.

The substrate polishing system may further include a stage portion to support the substrate wherein the stage portion is placed on a point on the transfer orbit.

The stage portion may be placed on the first point.

The stage portion may include a second nozzle to spray a fluid.

Additional aspects of example embodiments will be set forth in part in the description which follows and, in part, will be apparent from the description, or may be learned by practice of the disclosure.

According to example embodiments, a substrate polishing system may reduce time for a substrate polishing process by simultaneously performing transferring, polishing, and cleaning processes on a plurality of substrates.

According to example embodiments, a substrate polishing system may enhance a substrate yield rate by maintaining a substrate in a constant state during a process of transferring, waiting, and cleaning the substrate.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 is a schematic view of a substrate polishing system according to an example embodiment;

FIG. 2 is a schematic view of a substrate polishing system, viewed from a side according to an example embodiment;

FIG. 3 is a schematic top view of a substrate polishing system according to an example embodiment;

FIG. 4 is a schematic view of a substrate transfer unit rotated by a predetermined angle based on FIG. 3; and

FIG. 5 is a schematic view of a substrate transfer unit rotated by less than a predetermined angle based on FIG. 3.

### DETAILED DESCRIPTION

Hereinafter, example embodiments will be described in detail with reference to the accompanying drawings. However, various alterations and modifications may be made to the example embodiments. Here, the example embodiments are not construed as limited to the disclosure. The example embodiments should be understood to include all changes, equivalents, and replacements within the idea and the technical scope of the disclosure.

The terminology used herein is for the purpose of describing particular example embodiments only and is not to be limiting of the example embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the example embodiments with reference to the accompanying drawings, like reference numerals refer to like constituent elements and a repeated description related thereto will be omitted. In the description of example embodiments, detailed description of well-known related structures or functions will be omitted when it is deemed that such description will cause ambiguous interpretation of the present disclosure.

Also, in the description of the components, terms such as first, second, A, B, (a), (b) or the like may be used herein when describing components of the present disclosure. These terms are used only for the purpose of discriminating one constituent element from another constituent element, and the nature, the sequences, or the orders of the constituent elements are not limited by the terms. When one constituent element is described as being “connected”, “coupled”, or “attached” to another constituent element, it should be understood that one constituent element can be connected or attached directly to another constituent element, and an intervening constituent element can also be “connected”, “coupled”, or “attached” to the constituent elements.

The same name may be used to describe an element included in the example embodiments described above and an element having a common function. Unless otherwise mentioned, the descriptions on the example embodiments may be applicable to the following example embodiments and thus, duplicated descriptions will be omitted for conciseness.

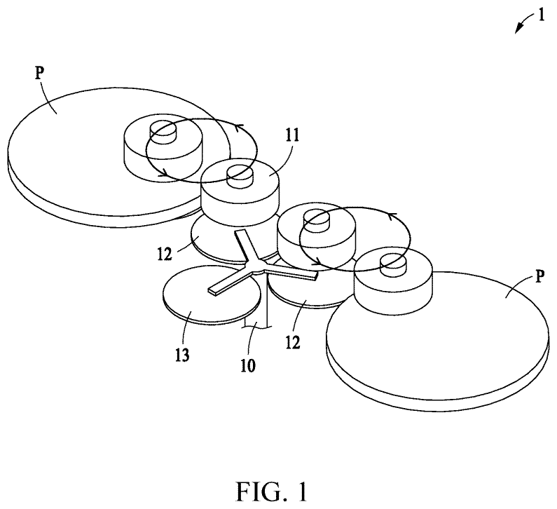

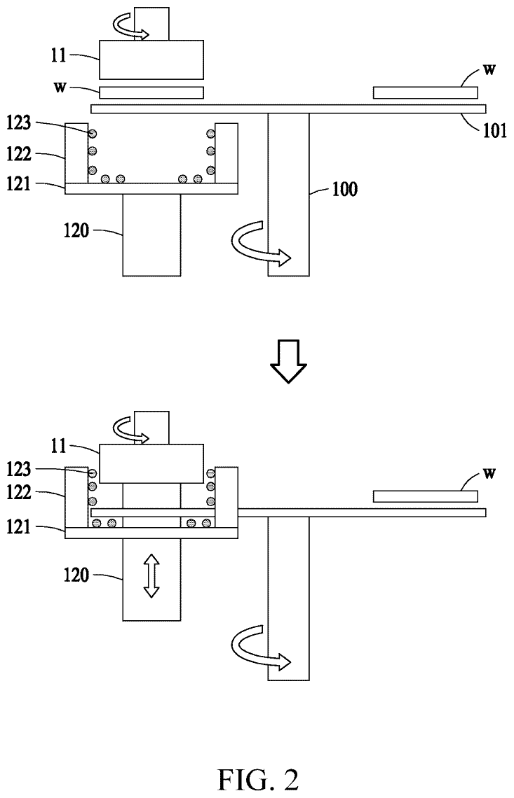

FIG. 1 is a schematic view of a substrate polishing system according to an example embodiment and FIG. 2 is a schematic view of a substrate polishing system, viewed from a side according to an example embodiment.

Referring to FIGS. 1 and 2, a substrate polishing system 1 may be used in a chemical mechanical polishing planarization (CMP) process to polish a surface of a substrate. A substrate polished by the substrate polishing system 1 may be a silicon wafer for manufacturing a semiconductor device. However, the type of the substrate is not limited to the foregoing example. For example, the substrate may include glass for a liquid crystal display (LCD) or a plasma display device (FPD). Although the drawings illustrate a substrate in a circular form, the example is only for ease of description and the form of the substrate is not limited to the one illustrated in the drawings.

The substrate polishing system 1 may include a substrate transfer unit 10, a carrier 11, a loader 12, and a stage portion 13.

The substrate transfer unit 10 may support a bottom surface of a substrate W. Specifically, the substrate transfer unit 10 may receive an unpolished substrate W from a return robot and may place the substrate W on an upper surface. In addition, the substrate transfer unit 10 may receive a polished substrate W from the carrier 11 and may place the substrate W on the upper surface. For example, the substrate transfer unit 10 may form a circular transfer orbit by rotation and may transfer the substrate W which is placed on the upper surface. The substrate transfer unit 10 may place a plurality of substrates W to simultaneously move an unpolished substrate W and a polished substrate W.

The substrate transfer unit 10 may include a shaft 100 and a transfer arm 101.

The shaft 100 may rotate on an axis perpendicular to a ground. The shaft 100 may rotate in one direction or in two directions.

The transfer arm 101 may support a bottom surface of the substrate W and may transfer the substrate W while forming a circular transfer orbit by rotation of the shaft 100. For example, the transfer arm 101 may be provided in a radial direction with the shaft 100 as a center and may form the circular transfer orbit by rotating in a rotation direction of the shaft 100 while connected to the shaft 100. In other words, a side of the transfer arm 101 may be connected to the shaft 100 and another side of the transfer arm 101 may support the substrate W.

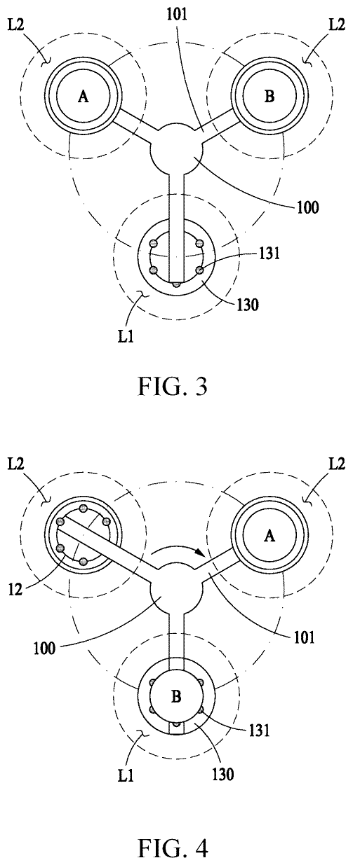

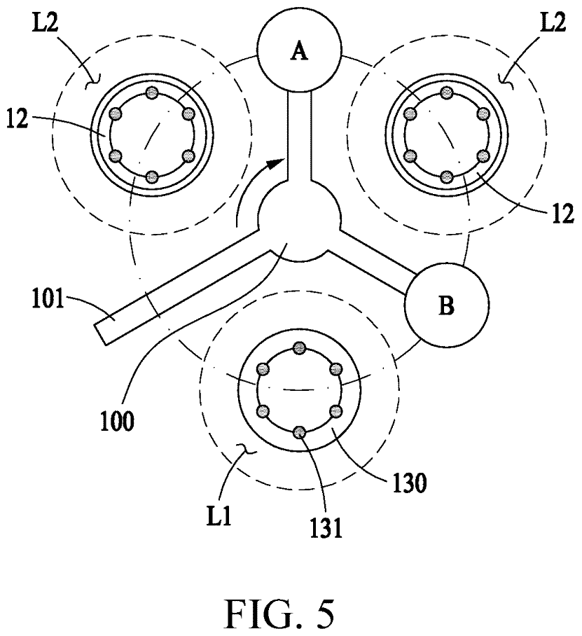

FIG. 3 is a schematic top view of a substrate polishing system according to an example embodiment. FIG. 4 is a schematic view of a substrate transfer unit rotated by a predetermined angle based on FIG. 3 and FIG. 5 is a schematic view of a substrate transfer unit rotated by less than a predetermined angle based on FIG. 3.

Referring to FIGS. 3 to 5, a plurality of transfer arms 101 may be provided and may each be disposed at an equiangular interval with the shaft 100 as a center. A portion of the plurality of transfer arms 101 may receive an unpolished substrate W and a portion of the plurality of transfer arms 101 may receive a polished substrate W. When one of the plurality of transfer arms 101 is placed on a first point L1, at least one of the plurality of transfer arms 101 may be placed on a second point L2. For example, the transfer arm 101 may receive an unpolished substrate W at the first point L1 on the transfer orbit and may transfer the unpolished substrate W to the carrier 11 by moving to the second point L2 on the transfer orbit. The carrier 11 may receive the unpolished substrate W from the transfer arm 101 and may perform polishing on the substrate W by moving to a polishing pad P which is described below. In addition, the carrier 11 may move to the substrate transfer unit 10 after performing a polishing process. The transfer arm 101 may receive the polished substrate W from the carrier 11 at the second point L2 and may transfer the polished substrate W to the first point L1 for a next process. The polished substrate W which is transferred to the first point L1 by the substrate transfer unit 10 may be transferred again by the return robot. The polished substrate W may be transferred for a next process such as a cleaning process by the return robot.

In the above-mentioned process, a polishing process may include a plurality of polishing processes and the second point L2 may include a plurality of points. For example, the substrate which is transferred from the first point L1 to one of the plurality of second points L2 may be returned to the substrate transfer unit 10 after the primary polishing process. The substrate W, on which the primary polishing process has been performed, returned to the substrate transfer unit 10, may be moved to another point of the plurality of the second points L2 by the substrate transfer unit 10 and may receive secondary polishing. The substrate W on which the secondary polishing process is performed may be transferred to the substrate transfer unit 10 and may be returned to the first point L1. As described above, a number of transfer arms 101 and a number of second points L2 may be adjusted based on a number of polishing processes.

The carrier 11 may receive a substrate W from the substrate transfer unit 10 and may perform polishing. The carrier 11 may grip the substrate W and may polish the substrate W by rotating. The carrier 11 may be placed on an upper side of the substrate W and may grip the substrate W in a way of enclosing the upper side and sides of the substrate W. For example, the carrier 11 may grip the substrate W by adsorption through a membrane (not shown). The carrier 11, gripping the substrate W by adsorption, may move to the polishing pad P and may perform polishing by frictionally placing the polishing pad P in contact with a polishing surface of the substrate W. The carrier 11 may rotate and/or translate (oscillate) for polishing the substrate W. In addition, the carrier 11 may move in a vertical direction perpendicular to the ground for loading/unloading the substrate W or polishing the substrate W.

The loader 12 may load a substrate W which is placed on the substrate transfer unit 10 to the carrier 11 or may unload the substrate W which is placed on the carrier 11 to the substrate transfer unit 10. The loader 12 may move vertically upwards or downwards from the substrate transfer unit 10. For example, the loader 12 may move upwards while supporting the substrate W which is placed on the substrate transfer unit 10 such that the carrier 11 may load the substrate W. In addition, the loader 12 may receive the substrate W gripped by the carrier 11 and may move downwards such that the carrier 11 may unload the substrate W.

The loader 12 may be placed at the second point L2. A plurality of loaders 12 may be provided which correspond to a plurality of second points L2.

The loader 12 may include a rotator 120, a loading plate 121, a protrusion 122 and a first nozzle 123.

The rotator 120 may rotate on an axis perpendicular to the ground. The loading plate 121 may be connected to the rotator 120 and may be rotated by the rotator 120. The loader 121 may support a bottom surface of the substrate W. That is, the rotator 120 and the loading plate 121 may move vertically and the substrate W placed on an upper surface of the loading plate 121 may be loaded to the carrier 11 or may be unloaded to the substrate transfer unit 10 according to a moving direction of the loading plate 121.

The protrusion 122 may be connected to an outside of the loading plate 121 and may protrude upwardly. For example, the protrusion 122 may be shaped like a pillar and be hollow inside. Specifically, when the loading plate 121 is shaped like a circle the protrusion 122 may be shaped like a pillar and be hollow inside. Viewed from the top, the protrusion 122 may have a radius greater than a radius of the carrier 11. In addition, during a process of loading or unloading the substrate W by moving the loader 12 upwards, the upper surface of the protrusion 122 may be placed higher than the bottom surface of the carrier 11.

Consequently, the structure of protrusion 122 may prevent the substrate W from escaping to the outside during the process of loading or unloading the substrate W by the loader 12. In addition, since the protrusion 122 is enclosed by an outer side of the carrier 11 and since the first nozzle 123, which is described below, is placed on an inside of the carrier 11, the carrier 11 may be more effectively cleaned by the nozzle 123.

The first nozzle 123 may spray a fluid. For example, the fluid may be a cleaning solution. In addition, the first nozzle 123 may be placed on the upper surface of the loading plate 121. In addition, the first nozzle 123 may be placed on the inside of the protrusion 122.

The loader 12 may remove a foreign material on a surface of the carrier 11 by spraying cleaning solution. Specifically, in a process of polishing the substrate W by an abrasive, the abrasive may be adhered and fixed to a membrane of the carrier 11. The abrasive adhered and fixed to the membrane may cause a chemical reaction and thus may affect a defect in the substrate W. As a result, the abrasive adhered and fixed to the membrane may deteriorate a yield rate of the substrate W. In this case, the abrasive may include a slurry. While the substrate W is transferred from the primary polishing process point to the secondary polishing process point by the substrate transfer unit 10, the loader 12 may reduce the time for the process of polishing the substrate W and may enhance the yield rate of the substrate W by removing the abrasive adhered and fixed to the surface of the carrier 11.

The loader 12 may clean the carrier 11 while the carrier 11 is not gripping the substrate W and may clean the carrier 11 while the carrier 11 is gripping the substrate W. Viewed from a side, the loader 12 may be placed at the same level as the carrier 11.

The stage portion 13 may be placed on a side on a transfer orbit and may support the substrate W. For example, the stage portion 13 may be placed at the first point L1 and may assist processes in which the substrate transfer unit 10 may receive the substrate W from the return robot, or the substrate transfer unit 10 may transfer the substrate W to the return robot. In addition, the stage portion 13 may assist the substrate W in waiting by supporting the bottom surface of the substrate W such that the substrate W may stably remain in a waiting state. Lastly, the stage portion 13 may spray a fluid to a surface of the substrate polishing system such that the substrate polishing system may remain in a constant state. The stage portion 13 placed below the substrate transfer unit 10 may move upwards or downwards in a state.

The stage portion 13 may include a stage plate 130 and a second nozzle 131.

The stage plate 130 may support the bottom surface of the substrate W. The stage plate 130 may or may not support the substrate W while moving downwards or upwards. The second nozzle 131 may be placed on an upper surface of the stage plate 130 and may spray a fluid. Specifically, the second nozzle 131 may spray a fluid to an upper surface of the substrate W while the state is waiting or transferring and may keep the substrate W moist. By the above-described function, the stage portion 13 may stably support the substrate W while preventing the substrate W from abrasion or being damaged by dryness by keeping the substrate W wet.

While this disclosure includes specific examples, it will be apparent to one of ordinary skill in the art that various changes in form and details may be made in these examples without departing from the spirit and scope of the claims and their equivalents.

The examples described herein are to be considered in a descriptive sense only, and not for purposes of limitation. Descriptions of features or aspects in each example are to be considered as being applicable to similar features or aspects in other examples. For example, suitable results may be achieved if the described techniques are performed in a different order and/or if components in a described system, architecture, device, or circuit are combined in a different manner and/or replaced or supplemented by other components or their equivalents.

Accordingly, other implementations are within the scope of the following claims.

1. A substrate polishing system comprising:
a substrate transfer unit to support a bottom surface of a substrate and transfer the substrate while forming a transfer orbit in a circle by rotating;
at least one carrier to perform polishing on the substrate received from the substrate transfer unit; and
a loader to load the substrate which is seated on the substrate transfer unit to the carrier or unload a substrate placed on the carrier to the substrate transfer unit, wherein the loader comprises:
a plurality of first nozzles to spray a fluid,
a rotator to rotate on an axis perpendicular to a ground,
a loading plate to support the bottom surface of the substrate, the loading plate being rotatable by the rotator, and
a protrusion connected to an outside of the loading plate and protruding upwardly,
wherein the plurality of first nozzles comprises a first inner nozzle and a second inner nozzle arranged on an inner surface of the protrusion,
wherein, during a process of loading or unloading the substrate by moving the loader upward, an upper surface of the protrusion is placed higher than a bottom surface of the carrier, the first inner nozzle is located above the bottom surface of the carrier, and the second inner nozzle is located below the bottom surface of the carrier,
wherein the substrate transfer unit comprises:
a shaft to rotate on an axis perpendicular to the ground; and
three transfer arms to support the bottom surface of the substrate and to transfer the substrate while forming the transfer orbit in the circle by rotation of the shaft,
wherein the three transfer arms are configured to receive an unpolished substrate at a first point on the transfer orbit and to transfer the unpolished substrate to the carrier by moving to each of a plurality of second points on the transfer orbit, and configured to receive a polished substrate from the carrier at each of the plurality of second points and to transfer the polished substrate to the first point for a next process,
wherein the three transfer arms are each disposed at an equiangular interval with the shaft as a center,
wherein when one of the three transfer arms is placed on the first point, each of the other two transfer arms is placed on one of the plurality of second points,
wherein the substrate polishing system further comprises a stage portion to support the substrate, wherein the stage portion is placed on the first point on the transfer orbit,
wherein the stage portion comprises a second nozzle which sprays a fluid to an upper surface of the substrate located on the stage portion while the substrate is waiting to be transferred and sprays a fluid to the upper surface of the substrate while the substrate is located on the stage portion and while the stage portion and the second nozzle are moving vertically upward or downward to keep the substrate moist,
wherein the plurality of first nozzles is configured to clean the carrier while the carrier is not gripping the substrate and to clean the carrier while the carrier is gripping the substrate, and
wherein the first inner nozzle and/or the second inner nozzle spray a fluid on the carrier while the substrate transfer unit is transferring the substrate from one of the plurality of second points to another of the plurality of second points,
wherein at least one of the plurality of first nozzles is further placed on an upper surface of the loading plate.

2. The substrate polishing system of claim 1, wherein the loader vertically moves upwards or downwards from the substrate transfer unit.

3. The substrate polishing system of claim 1, wherein the loader is placed on one of the plurality of second points.
